(19) United States
(12) Patent Application Publication
(10) Pub. No.: US 2004/0235297 A1
(43) Pub. Date: Nov. 25, 2004

(54) Reverse electroplating for damascene conductive region formation

(76) Inventor: Bih-Tiao Lin, Hsin-Chu (TW)

Correspondence Address: TAIWAN SEMICONDUCTOR MANUFACTURING CO., LTD., C/O SLATER & MATSIL, L.L.P., 17950 PRESTON ROAD, SUITE 1000, DALLAS, TX, 75252, US

(21) Appl. No.: 10/444,440

(22) Filed: May 23, 2003

(51) Int. Cl. H01L 21/44; H01L 21/4763

(52) U.S. Cl. 438/687; 438/645; 438/674

(57) ABSTRACT

A method of removing excess conductive material over a patterned insulating layer by reverse electroplating. A semiconductor wafer is submerged in an electroplating solution, and the semiconductor wafer functions as an anode in the reverse electroplating process. Bulk conductive material from the wafer surface is deposited to a cathode that is also submerged in the electroplating solution. Damascene conductive regions may be formed using the reverse electroplating process without causing damage to the top surface of the first insulating layer or causing dishing or erosion of top surface of the conductive material.

### TECHNICAL FIELD

The present invention relates generally to the fabrication of semiconductor devices, and more particularly to the fabrication of conductive regions of semiconductor devices using a damascene process.

### BACKGROUND

Semiconductor devices are used in many electronic applications, such as radios, televisions, cell phones and computers, as examples. Semiconductor devices are often fabricated as integrated circuits, with hundreds or thousands devices often being manufactured on a single chip.

Semiconductor devices are manufactured by depositing several insulating, conducting, and semiconductor layers over a workpiece, and then patterning each layer to form conductive lines and electrical circuit elements therein. Metallization layers are usually used for the interconnect layers of semiconductor devices. These metallization layers may have insulating layers or inter-level dielectric layers (ILD) disposed between each metallization layer, with vias formed within the ILD layer that provide vertical electrical connections throughout the semiconductor device.

For many years, aluminum was the preferred choice of material for interconnect layers of semiconductor devices. Aluminum is advantageous in that it may be patterned in a subtractive etch process, e.g., a layer of aluminum is deposited, photoresist is deposited over the aluminum layer, the photoresist is patterned, and then the photoresist is used as a mask while exposed portions of the aluminum are removed in a subtractive etch process.

However, to improve function and efficiency, copper is being used more and more as a material for interconnections because of its low resistivity, high melting point, and superior electromigration endurance. Copper is also advantageous as an interconnect material because of its stress-void resistance improvement over aluminum. However, copper is difficult to etch in a subtractive process; therefore, copper is usually patterned using damascene processes.

FIG. 1 illustrates a cross-sectional view of a semiconductor device 100 in which conductive lines will be formed in a damascene process. The fabrication of the semiconductor device 100 in accordance with a prior art damascene process will next be described. A workpiece 110 which may comprise a silicon wafer, for example, is provided. An insulating layer 112 is deposited or formed over the workpiece 110. The insulating layer 112 is patterned, for example, using traditional photolithography techniques and a photoresist. The pattern formed in the insulating layer 112 comprises a pattern for conductive lines. A liner (not shown) may be deposited over the insulating layer 112, particularly if the conductive lines comprise copper, for example. A conductive material 114, which may comprise copper, for example, is deposited over the liner, as shown. The conductive material 114 has a top surface that is relatively conformal to the underlying topography of the insulating layer 112. For example, the conductive material 114 may have a recess 118 formed over the top of the trench in the insulating layer 112 for the conductive lines.

To form conductive lines 116 in the insulating layer 112, the insulating layer 112 is planarized, for example, using a chemical-mechanical polish (CMP) process to remove the conductive material 114 and the liner from the top surface of the insulating layer 112, as shown in FIG. 2. A disadvantage of using a CMP process to remove excess conductive material 114 and liner from the top surface of the insulating layer 112 is that the copper material 114 dishes or forms a recess 118 below the top surface of the insulating layer 112, as shown. The erosion, recess or dishing 118 of the copper material 114 is undesirable because the conducting area of the conductive lines 116 is reduced and the sheet resistance of the conductive lines 116 is increased.

What is needed in the art is a method of forming copper damascene conductive lines that results in reduced dishing, or preferably, results in no dishing at all, of the top surface of the copper conductive lines 116.

Another problem with the damascene process shown in FIGS. 1 and 2 arises if low-k insulating materials are used for the insulating layer 112, as is common when copper is used as the material for conductive lines, in order to reduce the R-C time delay of the conductive lines. These low-k insulating materials are typically very soft and fragile, and thus are easily damaged. The CMP process is adapted to stop on the insulating layer 112, which may result in the formation of micro-scratches 120 on the top surface of the insulating layer 112. Erosion of the insulating layer 112 may result in defects, because of the fragile characteristics of the low-k dielectric material.

Therefore, what is also needed in the art is a method of forming copper damascene conductive lines that does not result in damage to the top surface of the insulating layer 112.

### SUMMARY OF THE INVENTION

These and other problems are generally solved or circumvented, and technical advantages are generally achieved, by preferred embodiments of the present invention, which provide a method of forming damascene conductive regions by reverse electrolysis or reverse electroplating. The semiconductor wafer is used as the anode in an electroplating process, rather than as a cathode, which is the case in traditional electroplating processes for forming copper on a semiconductor wafer surface. Because the wafer functions as an anode, copper is removed from the wafer surface. The reverse electroplating process disclosed herein is used in place of a CMP process to remove excess copper material from over a patterned damascene insulating layer, thus preventing damage to the top surface of the insulating layer from the CMP process. An end-point detector can be used to determine when the copper has been completely removed from the top surface of the insulating layer and stop the reverse electroplating process, which avoids excess removal of the copper from beneath the insulating layer top surface.

In accordance with a preferred embodiment of the present invention, a method of forming conductive regions of a semiconductor device includes providing a workpiece, the workpiece having an insulating layer disposed thereon, the insulating layer being patterned with a pattern for at least one conductive region and having a top surface, and the workpiece including a conductive material formed over the patterned insulating layer. The conductive material is reverse electroplated to remove a portion of the conductive material from over the insulating layer.

In accordance with another preferred embodiment of the present invention, a method of forming copper conductive regions of a semiconductor device includes providing a workpiece, forming an insulating layer over the workpiece, the insulating layer having a top surface, and patterning the insulating layer with a pattern for at least one conductive region. A liner is formed on the insulating layer, a copper layer is formed on the liner, and the copper layer is planarized to form a smooth top surface on the copper layer. The method includes reverse electroplating the copper layer to remove at least a portion of the copper layer from over the insulating layer.

An advantage of a preferred embodiment of the present invention includes providing a method of removing excess conductive material from over an insulating layer when a damascene process is used to form conductive regions. The reverse electroplating process provides a method of removing bulk copper and other conductive materials from over a wafer, while avoiding damage to the underlying insulating layer top surface and without leaving recesses in the copper or conductive material top surface. Wafer non-uniformity is controlled by optimizing the anode-electrode distribution on the wafer. Over-electrolysis can be avoided with the use of an end-point detector.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 and 2 illustrate cross-sectional views of a prior art damascene process for forming conductive regions of a semiconductor device, wherein the CMP process causes micro-scratches and erosion of the insulating layer, and the copper is recessed or dished by the CMP process;

FIGS. 3 through 6 show cross-sectional views of a reverse electroplating process for forming damascene conductive regions in accordance with a first embodiment of the present invention; and

FIGS. 7 and 8 show cross-sectional views of another embodiment of the present invention, wherein a reverse electroplating process is used to form a dual damascene structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a semiconductor device having conductive regions or conductive lines that comprise a copper material or copper alloy. Embodiments of the present invention may also be applied, however, to semiconductor devices having conductive regions and lines formed out of other conductors or metals, as examples. Only one conductive region is shown in each figure; however, there may be many other conductive regions formed in the layers shown.

When copper is used as a conductive material for metallization layers of semiconductor devices, it is desirable that the recesses or trenches formed in the underlying insulating layers are completely filled, and have no voids or seams, as examples. To avoid void and seam formation, especially in regions of semiconductor devices having minimum feature sizes, for example, frequently copper is deposited into and over the insulating layer by electroplating or electroless-plating. While copper may also be deposited by physical vapor deposition (PVD) or chemical vapor deposition (CVD), depositing copper by metal plating may be done at a high throughput and therefore at a lower cost. Furthermore, electroplating copper may be achieved at temperatures of 40 degrees C. or less, and electroplating also can fill high-aspect ratio structures, e.g., having an aspect ratio of 5:1.

In an electroplating process, solutions containing ions of the metal to be deposited are utilized. For copper electroplating, the electroplating solution typically contains copper sulfate (CuSO₄), sulfuric acid (H₂SO₄), and water, as examples. The surface on the semiconductor wafer to be plated is typically coated with a copper seed layer that is deposited over a barrier layer such as TiN, or bi-layer of Ta and TaN, as examples, and the wafer is submerged or immersed in the electroplating solution. The wafer surface is electrically connected to the negative side of an external DC power supply. The wafer functions as the cathode in the electroplating process. A solid copper anode is also immersed in the solution and is attached to the positive side of the power supply. The copper atoms of the anode are oxidized to form Cu²⁺ ions. The Cu²⁺ ions are released from the anode and dissolve into the solution. As the positive copper ions arrived at the negative-biased cathode, e.g., the wafer, they acquire two electrons and are reduced to copper metal which plates out on the wafer surface. The metal ion formation reaction is sustained by passing an electrical current through the electroplating solution.

Embodiments of the present invention achieve technical advantages by reversing the traditional electroplating process to remove a conductive material such as copper from a wafer surface, rather than depositing it, as in traditional electroplating techniques. In accordance with embodiments of the invention, the semiconductor wafer functions as the anode in a reverse electroplating technique, and a solid copper cathode is used to collect the copper ions that leave the semiconductor wafer surface. The reverse electroplating technique described herein may be used to remove excess copper material from over damascene structures to form conductive regions or lines of a semiconductor device, to be described further herein.

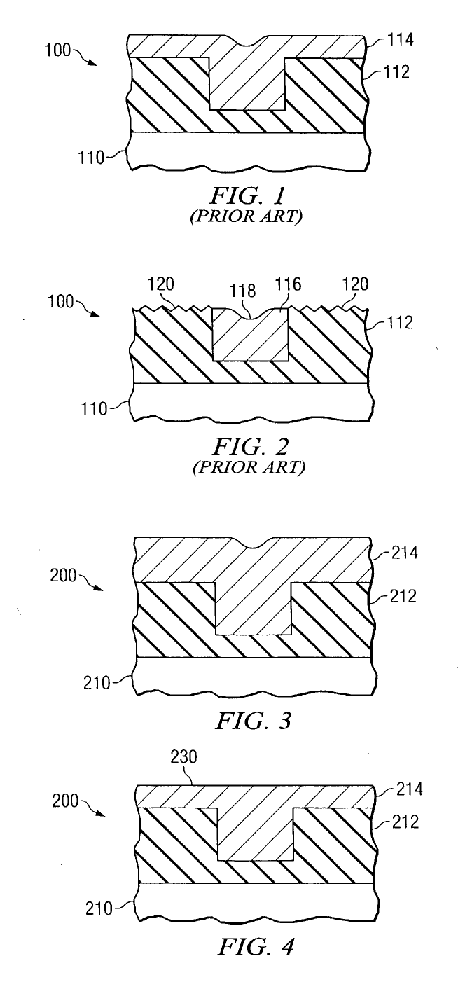

With reference now to FIG. 3, there is shown a semiconductor device 200 in which damascene conductive regions will be formed. A semiconductor wafer comprising a workpiece 210 is provided. The workpiece 202 typically comprises silicon oxide over a single crystal silicon wafer. The workpiece 202 may include other conductive layers or other semiconductor elements, e.g., transistors, diodes, etc. (not shown). Compound semiconductors such as GaAs, InP, Si/Ge, SiC, for example, may be used in place of silicon.

A first insulating layer 212 is deposited over the workpiece 210. The insulating layer 212 may comprise a dielectric material, such as silicon dioxide, silicon nitride, or low-k dielectric materials, as examples. Alternatively, the insulating layer 212 may comprise other dielectric materials, such as high-k dielectric materials, for example.

The insulating layer 212 is patterned with a trench or recess for at least one conductive region. For example, a photoresist may be deposited over the insulating layer 212, and the photoresist may be patterned, for example, using a lithography mask, and the photoresist may be exposed to energy or light to pattern the photoresist. Unexposed (or exposed, depending on if the photoresist is positive or negative) portions of the photoresist are removed, and the photoresist is used to pattern the underlying insulating layer 212, not shown. The photoresist is then stripped or removed from the top surface of the insulating layer 212.

A conductive material 214 is deposited over the patterned insulating layer 212. The conductive material 214 may comprise pure copper, a copper alloy, aluminum, other conductive materials, or combinations thereof, as examples, although the conductive material 214 may alternatively comprise other metals. The conductive material 214 preferably comprises a metal that may be electroplated. The conductive material 214 may be substantially conformal to the underlying patterned insulating layer 212, and in particular, the conductive material 214 may have a recess formed over trenched regions of the insulating layer 212, as shown.

Referring next to FIG. 4, preferably, in accordance with embodiments of the present invention, the top surface of the conductive material 214 is planarized to form a smooth, planar top surface on the conductive material. The conductive material 214 may be planarized using a CMP process, for example. Preferably the planarization process comprises a timed CMP process that stops before the top surface of the insulating layer 212 is reached.

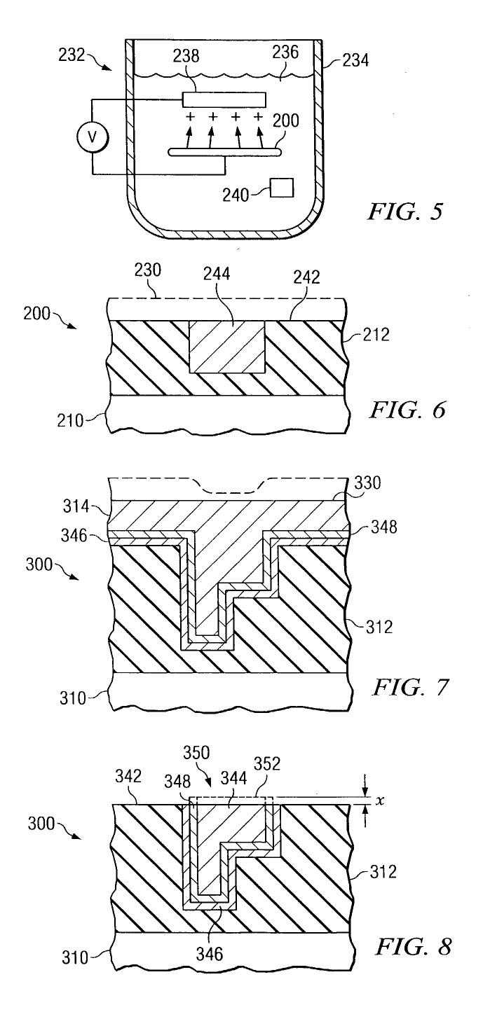

The workpiece 210 is placed into an electrolysis solution 236 in a vat 234 which may comprise a part of an electrolysis chamber or system 232. As shown in FIG. 5, the electroplating solution 236 may comprise an electroplating solution similar to one used for an electroplating process, for example. If the conductive material 214 comprises copper, the electroplating solution preferably comprises CuSO₄, although the electroplating solution may alternatively comprise other chemistries, for example. A cathode 238 is also submerged in the electroplating solution 236. The cathode 238 may comprise a solid copper rod, for example. A voltage source is coupled to the cathode 238 and to the workpiece 210, which functions as the anode. The cathode 238 is preferably coupled to the negative side of the voltage source, and the semiconductor wafer or workpiece 210 is preferably coupled to the positive side of the voltage source.

A voltage V is applied across the anode 200 and cathode 238, and an electrolysis reaction occurs, transferring or depositing bulk copper or conductive material 214 from the workpiece 200 to the cathode 238. A uniform voltage is preferably placed across the workpiece 200 to optimize the anode-electro distribution on the wafer 200.

In accordance with an embodiment of the present invention, an end-point detector 240 is used to detect the copper ion concentration in the electrolysis solution 236. The end-point detector 240 determines when the conductor material 214 is completely removed from the top surface of the insulating layer 212, by measuring the electric current of the electrolysis reaction. The end-point detector 240 may detect a decrease in current when the top surface of the insulating layer 212 is reached, because less copper is being released from the workpiece 210 surface into the solution, for example. The electroplating system 232 may be designed so that the reverse electroplating process is stopped when the end-point detector 240 detects this decrease in current. The end-point detector 240 is advantageous in that excessive recessing of the conductive material 214 beneath the top surface of the insulating layer 212 in the trench can be avoided.

In accordance with an embodiment of the invention, reverse electroplating the conductive material comprises removing at least a portion of the conductive material 214, e.g., partially, from over the top surface of the insulating layer 212. In accordance with another embodiment of the present invention, reverse electroplating the conductive material 214 comprises removing the conductive material 214 completely from the top surface of the insulating layer 212, as shown in FIG. 6, to form a conductive region 244. The conductive region 244 may comprise a conductive line or may comprise a contact pad or conductive area having a square or circular shape, as examples, although the conductive region 244 may alternatively comprise other shapes.

The reverse electroplating process described herein may be used for damascene structures comprising copper or any other conductive material that may be electroplated, for example. Embodiments of the present invention may be used in a single damascene structure, such as the single damascene structure shown in FIGS. 3 through 6, and alternatively, the reverse electroplating process may be used in dual damascene structures, such as the one shown in FIGS. 7 and 8, which will next be described.

In a dual damascene structure, the insulating layer 312 is typically patterned in two separate patterning steps, for example, using two different masks. FIG. 7 shows a dual damascene structure having a first pattern portion, e.g., the deeper pattern, and a second pattern portion, e.g., the shallower pattern.

In accordance with an embodiment of the invention, when the conductive material 314 comprises copper, preferably, a liner 346/348 is deposited over the patterned insulating layer 312 before the conductive material 314 is deposited, as shown in FIG. 7. The liner 346/348 may comprise a barrier layer 346 and a copper seed layer 348. The barrier layer 346 preferably comprises a layer of Ta and a layer of TaN in a thickness of 5 to 100 nm, for example. The copper seed layer 348 may comprise copper or a copper alloy deposited in a thickness of 5 to 100 nm, for example. Alternatively, the barrier layer 346 and copper seed layer 348 may comprise other materials and thicknesses, for example.

The conductive material 314 is deposited over the liner 346/348. The top surface of the conductive material 314 is planarized to form a smooth, even, top surface 330. The semiconductor wafer 310 is then immersed in the electroplating solution 236 as shown in FIG. 5, and a reverse electroplating process is used to remove a portion of the conductive material 314 from above the top surface of the insulating layer 312, as shown in FIG. 8.

Note that when a barrier layer 346 and a copper seed layer 348 are used, the copper seed layer 348 is also removed during the reverse electroplating process, as shown in FIG. 8. However, an additional etch process is required to remove the barrier layer 346 from the top surface of the insulating layer 312. The etch process to remove the barrier layer 346 may comprise a dry etch using a chlorine or fluorine chemistry, for example. Alternatively, the etch process to remove the barrier layer 346 may comprise a CMP process, preferably using a soft pad so that the generation of micro-scratches in the top surface of the insulating layer 312 is avoided. Note that when an etch process is used to remove the excess barrier layer 346 from over the top surface of the insulating layer 312, the conductive material 344 and copper seed layer 348 may comprise a slightly greater height 352 than the top surface 342 of the insulating layer 312, as shown in FIG. 8. The conductive line 344 and seed layer 348 may exceed the height of the insulating layer 312 by an amount x, for example, as shown. However, the additional topography comprises only an additional 5 to 100 μnm protrusion, for example. The top surface of the workpiece 310 may be planarized by the deposition of a subsequent dielectric film having a smooth top surface (not shown).

Embodiments of the present invention achieve technical advantages by providing a method of reverse electroplating a conductive material 214/314 to remove excess conductive material 214/314 from over patterned insulating layers 212/312 and form damascene conductive regions 244/344. Damage of the insulating layer 212/312 due to micro-scratches and recessing of the top surface of the conductive material 214/314 are avoided, because a CMP process is not utilized. Advantageously, when a barrier layer 346 is used, the insulating layer 312 is not exposed to the electroplating solution 236 during the reverse electroplating process. An end-point detector 240 may be used to avoid removing excessive amounts of conductive material 214/314 from beneath the top surface of the insulating layer 212/312. The reverse electroplating method described herein has a high throughput, and thus provides a cost and labor savings in the manufacturing of semiconductor devices 200/300 having damascene conductive regions 244/344.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method of forming conductive regions of a semiconductor device, the method comprising:
providing a workpiece, the workpiece having an insulating layer disposed thereon, the insulating layer being patterned with a pattern for at least one conductive region and having a top surface, the workpiece including a conductive material formed over the patterned insulating layer;
planarizing the conductive material forming a planarized surface; and
reverse electroplating the planarized surface of the conductive material to remove a portion of the conductive material from over the insulating layer.

2. The method according to claim 1, wherein reverse electroplating the conductive material comprises removing the conductive material completely from the top surface of the insulating layer.

3. The method according to claim 2, further comprising using an end-point detector to determine when the conductive material is completely removed from the top surface of the insulating layer.

4. Cancelled

5. The method according to claim 1, wherein planarizing the workpiece comprises a chemical-mechanical polish process.

6. The method according to claim 1, wherein reverse electroplating the conductive material comprises:
providing a electroplating solution and a cathode submerged in the electroplating solution;
submerging the workpiece into the electroplating solution, wherein the workpiece comprises an anode; and
applying a voltage across the cathode and anode.

7. The method according to claim 6, wherein the conductive material comprises copper, and wherein providing the electroplating solution comprises providing a solution containing CuSO₄.

8. The method according to claim 6, further comprising providing an end-point detector for the reverse electroplating process.

9. The method according to claim 8, wherein the end-point detector is adapted to measure the electric current of an electrolysis process caused by the applied voltage.

10. The method according to claim 1, wherein the at least one conductive region comprises at least one conductive line.

11. The method according to claim 1, wherein the insulating layer is patterned with a damascene or dual-damascene process.

12. The method according to claim 1, wherein the workpiece includes a liner disposed between the insulating layer and the conductive material, further comprising removing the liner from the top surface of the insulating layer.

13. A method of forming copper conductive regions of a semiconductor device, the method comprising:
providing a workpiece;
forming an insulating layer over the workpiece, the insulating layer having a top surface;
patterning the insulating layer with a pattern for at least one conductive region;
forming a liner on the insulating layer;
forming a copper layer on the liner;
planarizing the copper layer to form a smooth top surface on the copper layer; and
reverse electroplating the copper layer to remove at least a portion of the copper layer from over the insulating layer.

14. The method according to claim 13, wherein reverse electroplating the copper layer comprises removing the copper layer completely from the top surface of the insulating layer.

15. The method according to claim 14, further comprising using an end-point detector to determine when the copper layer is completely removed from the top surface of the insulating layer.

16. The method according to claim 15, wherein the end-point detector is adapted to measure the electric current of the reverse electrolysis process.

17. The method according to claim 13, wherein planarizing the copper layer comprises a chemical-mechanical polish process.

18. The method according to claim 13, wherein reverse electroplating the copper comprises:
providing a electroplating solution and a cathode submerged in the electroplating solution;
submerging the workpiece into the electroplating solution, wherein the workpiece comprises an anode; and
applying a voltage across the cathode and anode.

19. The method according to claim 17, wherein the copper comprises copper, and wherein providing the electroplating solution comprises providing a solution containing CuSO₄.

20. The method according to claim 19, further comprising providing an end-point detector, wherein the end-point detector is adapted to measure the electric current of an electrolysis process caused by the applied voltage.

21. The method according to claim 13, wherein the at least one conductive region comprises at least one conductive line.

22. The method according to claim 13, wherein the insulating layer is patterned with a damascene or dual-damascene process.

23. The method according to claim 13, wherein forming the liner comprises:
forming a barrier layer on the insulating layer; and
forming a copper seed layer on the barrier layer.

24. The method according to claim 23, wherein forming the barrier layer comprises depositing a layer of Ta and depositing a layer of TaN, wherein the barrier layer is formed in a thickness of 5 to 100 nm.

25. The method according to claim 23, wherein forming the copper seed layer comprises forming a copper seed layer having a thickness of 5 to 100 nm.

26. The method according to claim 23, wherein reverse electroplating the copper layer further comprises reverse electroplating the copper seed layer to remove the copper seed layer from over the insulating layer.

27. The method according to claim 26, further comprising removing the barrier layer from over the top surface of the insulating layer.

28. The method according to claim 27, wherein removing the barrier layer comprises a using a dry etch or a chemical-mechanical polish (CMP) process.

29. The method according to claim 13, wherein planarizing the copper layer does not comprise planarizing a top surface of the insulating layer.
